(19) United States
(12) Patent Application Publication
(10) Pub. No.: US 2016/0293592 A1
(43) Pub. Date: Oct. 6, 2016

(54) THIN BI-DIRECTIONAL TRANSIENT VOLTAGE SUPPRESSOR (TVS) OR ZENER DIODE

(71) Applicant: VISHAY GENERAL SEMICONDUCTOR LLC, Hauppauge, NY (US)

(72) Inventors: Shih-Kuan Chen, New Taipei City (TW); Wan-Lan Chiang, Taipei (TW); Ming-Tai Chiang, Taipei (TW); Cheng-Hao Chang, Taipei (TW)

(21) Appl. No.: 14/673,910

(22) Filed: Mar. 31, 2015

(51) Int. Cl. H01L 27/02; H01L 29/66

(52) U.S. Cl. CPC H01L 27/0259; H01L 29/66234

(57) ABSTRACT

A bidirectional transient voltage suppressor includes a semiconductor substrate having a first conductivity type; a first epitaxial semiconductor layer having a second conductivity type formed on a first side of the semiconductor substrate; a second semiconductor layer having the first conductivity type formed on the first epitaxial semiconductor layer; and a first and second metallization layers disposed on a second side of the semiconductor substrate and the second semiconductor layer, respectively.

### BACKGROUND

Voltages and current transients are major causes of integrated circuit failure in electronic systems. Transients are generated from a variety of sources both internal and external to the system. For instance, common sources of transients include normal switching operations of power supplies, AC line fluctuations, lightning surges, and electrostatic discharge (ESD).

Transient voltage suppressors (TVS) are commonly employed for protecting integrated circuits from damages due to the occurrences of transients or over-voltage conditions at the integrated circuit. TVS devices are either uni-directional devices or bi-directional devices. An increasing number of electronic devices require bi-directional TVS protection as these electronic devices are manufactured with components that are vulnerable to transient voltages having positive or negative voltage polarity. For instance, bi-directional TVS devices are used for protecting high-speed data lines in applications such as portable handheld devices, keypads, notebook computers, digital cameras, and portable GPS and MP3 players.

There are many schemes for implementing a bi-directional TVS. One such scheme is shown in FIG. 1, in which each P/N junction of the bi-directional TVS 100 is formed on opposite sides of a die 110. In FIG. 1 an N-P-N junction structure is shown in which two N+ layers 120 and 130 are formed on opposite sides of the die 110. Contact metals 150 and 160 are respectively formed on the N+ layers 120 and 130. Passivation layers 140 and 170 are also formed on both sides of the die 110 to protect the junctions. The bi-directional TVS 100 shown in FIG. 1 has a mesa type structure. As shown in FIG. 2, the bi-directional TVS 100 may also have a planar structure. In FIGS. 1 and 2 like elements are denoted by like reference numerals. While the devices shown in FIGS. 1 and 2 show an N-P-N junction structure, a P-N-P junction structure may be formed in a similar manner.

The monolithic bi-directional TVS devices shown in FIGS. 1 and 2 clearly require a double sided fabrication process. This can be difficult for a number of reasons. For instance, pattern alignment can be difficult to achieve and damage may be caused both by handling of a thin wafer in general and in particular by handling of the back-side of the device while fabricating the other side.

Another type of bi-directional TVS is a low voltage punch-through TVS. Such a TVS may be implemented using an NPN or PNP configuration. A punchthrough diode based TVS is usually formed as a stacked structure of multiple doped layers, such as a four-layer structure including a P+/N/P+/P++ or N+/P/N+/N++ structure. In a P+/N/P+/P++ device the middle N-type layer is relatively thin, so the depletion width of the topmost P/N junction extends into the bottommost P/N junction.

### SUMMARY

In accordance with one aspect of the invention, a bidirectional transient voltage suppressor is provided. The bidirectional transient voltage suppressor includes a semiconductor substrate having a first conductivity type; a first epitaxial semiconductor layer having a second conductivity type formed on a first side of the semiconductor substrate; a second semiconductor layer having the first conductivity type formed on the first epitaxial semiconductor layer; and a first and second metallization layers disposed on a second side of the semiconductor substrate and the second semiconductor layer, respectively.

In accordance with another aspect of the invention, a method of forming a bidirectional transient voltage suppressor is provided. In accordance with the method, a first epitaxial semiconductor layer is formed. The first epitaxial layer has a second conductivity type formed on a first side of a semiconductor substrate having a first conductivity type. A second semiconductor layer having the first conductivity type is formed on the first epitaxial semiconductor layer. First and second metallization layers are formed on a second side of the semiconductor substrate and the second semiconductor layer, respectively.

### BRIEF DESCRIPTION OF THE DRAWINGS

FIG. 1 shows a conventional bi-directional TVS.

FIG. 2 shows another conventional bi-directional TVS.

FIG. 3a shows a schematic circuit diagram of a P-N-P bi-polar junction transistor and FIG. 3b shows a schematic circuit diagram of an N-P-N bi-polar junction transistor.

FIGS. 4a and 4b are schematic circuit diagrams of a P-N-P transient voltage suppressor with the base being disconnected from the circuit.

FIGS. 5a and 5b show circuit diagrams of an N-P-N transient voltage suppressor.

FIG. 6 shows a schematic, cross-sectional view of one example of a P-N-P bi-directional transient voltage suppressor.

FIG. 7 shows a schematic, cross-sectional view of one example of an N-P-N bi-directional transient voltage suppressor.

FIG. 8 is a Table showing sample results for values of the breakdown voltages V_{z}1 and V_{z}2 for transient voltage suppressors fabricated in accordance with the techniques discussed herein.

FIG. 9 is a Table showing measured breakdown voltages for transient voltage suppressors fabricated in accordance with the techniques discussed herein.

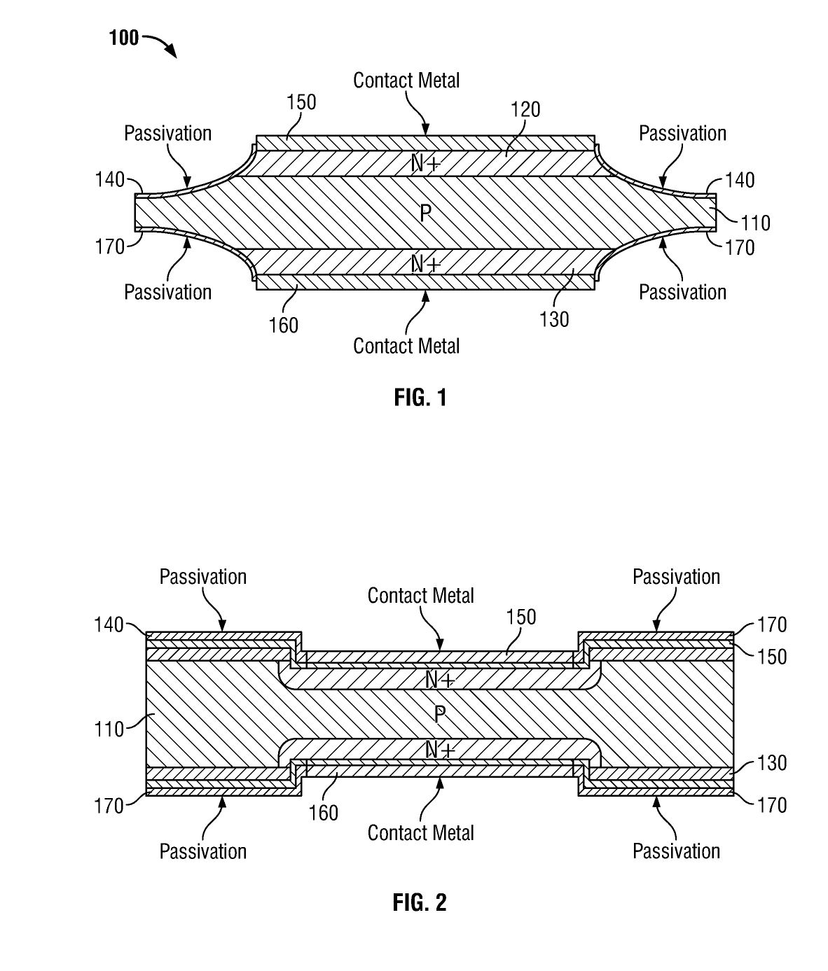

### DETAILED DESCRIPTION

The following description provides specific details for a thorough understanding of embodiments of a semiconductor device and formation process. However, one skilled in the art will understand that the device and process described herein may be practiced without these details. In other instances, well-known structures and functions have not been shown or described in detail to avoid unnecessarily obscuring the description of the embodiments described herein.

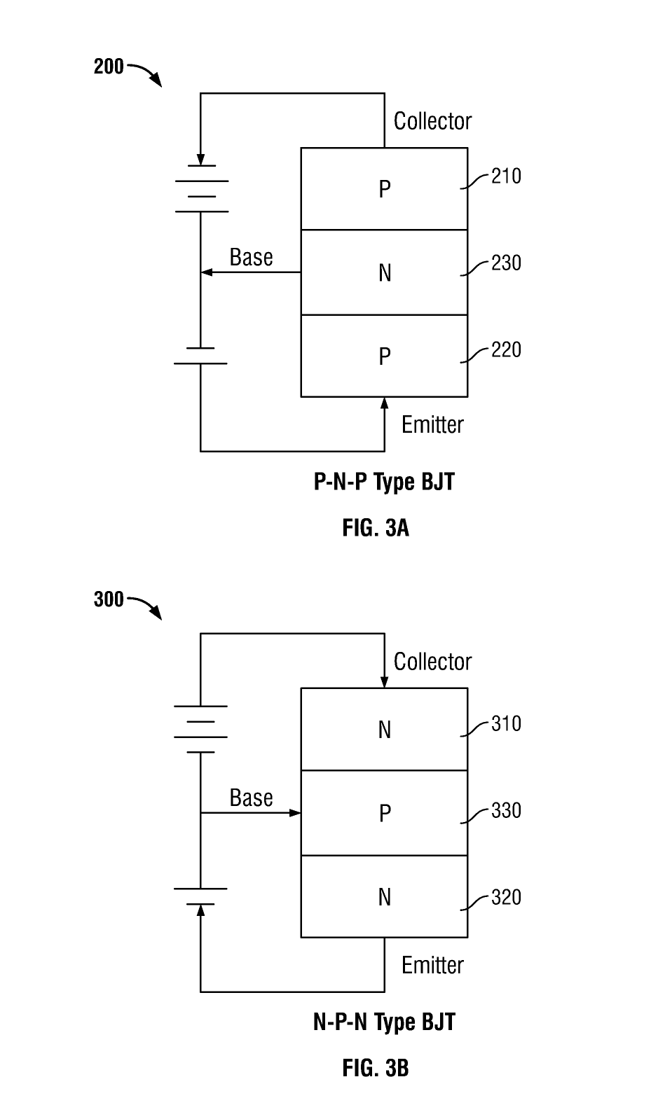

As detailed below, in accordance with one aspect of the disclosed subject matter, a bi-directional transient voltage suppressor (TVS) or Zener diode may be formed by appropriate modification of a bi-polar junction transistor (BJT). A BJT is a three terminal device that includes two P/N junctions formed from three differently doped regions. FIG. 3a shows a schematic circuit diagram of an P-N-P BJT 200 in which an N-doped layer 230 is interposed between P-doped layers 210 and 220. The N-doped layer 230 serves as the base and the P-doped layers 210 and 220 serve as the collector and emitter, respectively. Likewise, FIG. 3b shows a schematic circuit diagram of an N-P-N BJT 300 in which a P-doped layer 330 is interposed between N-doped layers 310 and 320. The P-doped layer 330 serves as the base and the N-doped layers 310 and 320 serve as the collector and emitter, respectively. The various layers are biased as shown in FIGS. 3a and 3b.

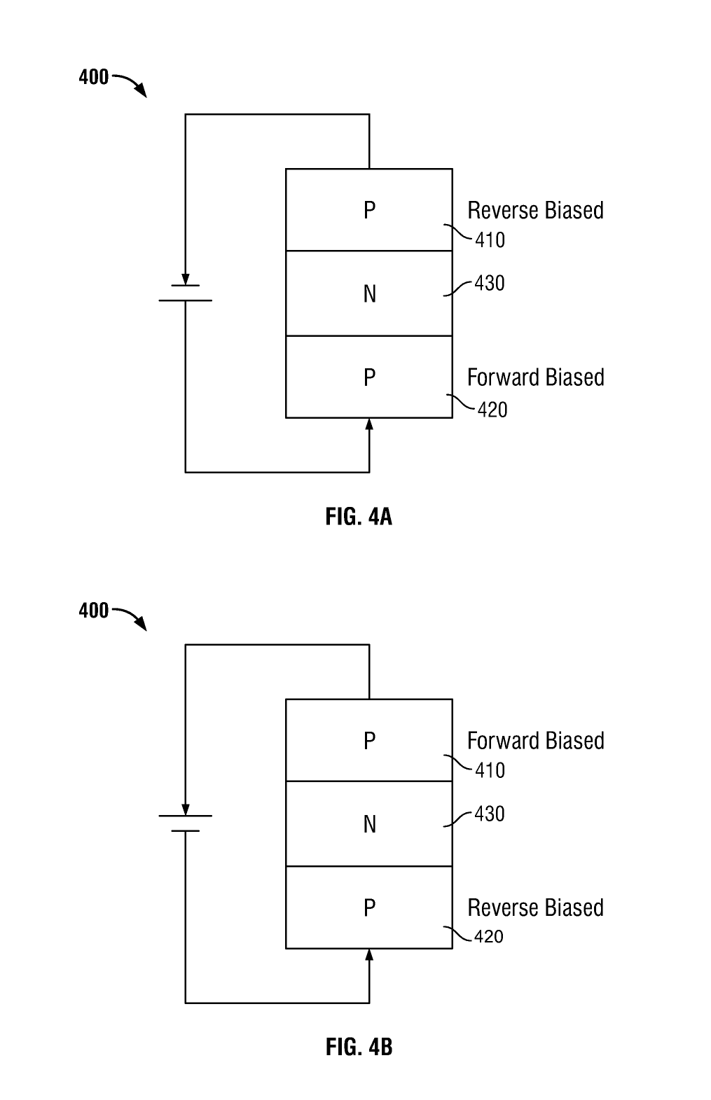

If the base terminals in the BJTs shown in FIGS. 3a and 3b are disconnected from the circuits, the devices, which are now two-terminal devices, will act as bi-directional TVSs or Zener diodes. FIGS. 4a and 4b are schematic circuit diagrams of a P-N-P TVS 400 with the base 430 being disconnected as shown. The TVS 400 includes an N-doped layer 430 interposed between P-doped layers 410 and 420. The P-doped layers 410 and 420 serve as the collector and emitter, respectively. The two P/N junctions are connected back-to-back. When a bias is applied in either direction, one junction is forward biased and the other is reverse biased, which is the desired functionality of bi-directional TVS or Zener diode device. FIG. 4b shows a circuit diagram of the TVS 400 of FIG. 4a with the biases of the two junctions reversed.

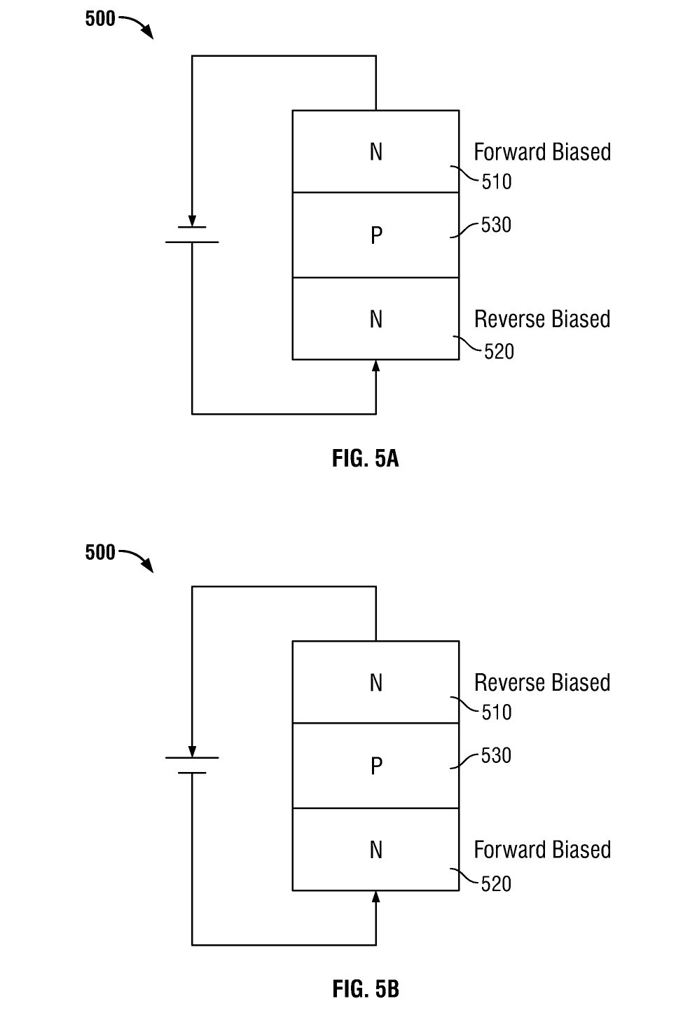

FIGS. 5a and 5b show circuit diagrams of N-P-N TVS 500, which include a P-doped layer 530 interposed between N-doped layers 510 and 520. The N-doped layers 510 and 520 serve as the collector and emitter, respectively. The two P/N junctions are connected back-to-back. When a bias is applied in either direction, one junction is forward biased and the other is reverse biased, which is the desired functionality of bi-directional TVS or Zener diode device. In FIGS. 5a and 5b the biases of the two junctions are reversed with respect to one another.

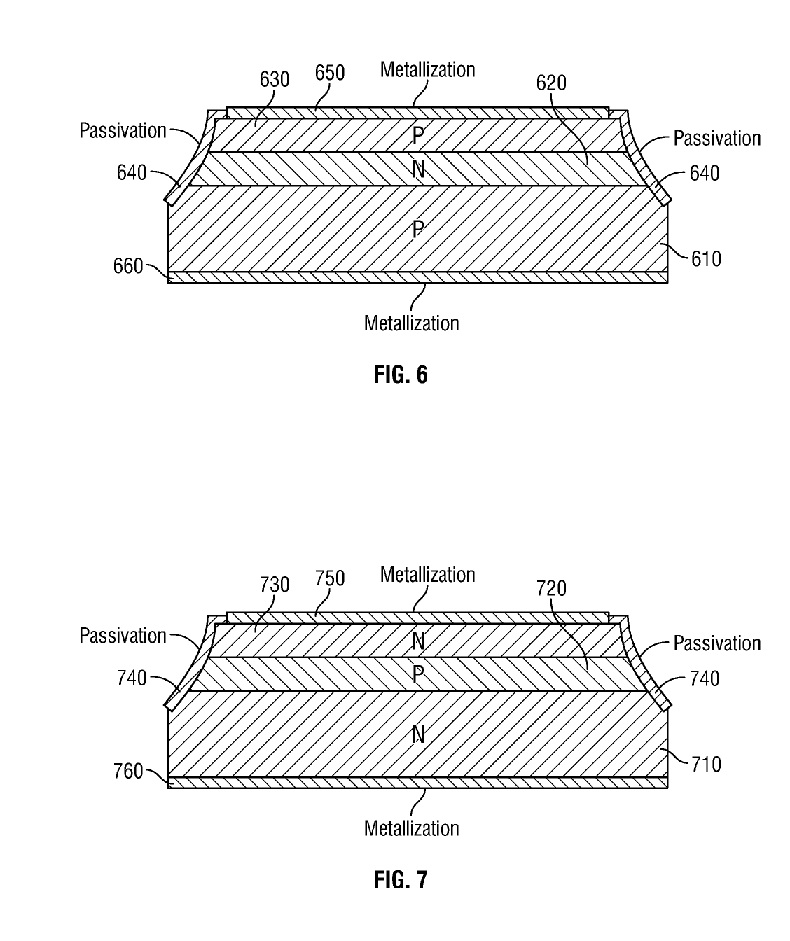

FIG. 6 shows a schematic, cross-sectional view of one example of a P-N-P bi-directional TVS 600. The TVS is formed on a P-type semiconductor substrate 610. On the P-type substrate 610 two regions or layers are grown. A first epitaxial N-type layer 620 is initially formed on the upper surface of P-type substrate 610. A P-type layer 630 is then formed on the upper surface of the N-type layer 620. The P-type layer 630 may be formed by an epitaxial deposition process. Alternatively, the P-type layer 630 may be formed using a doping process. For example, a P-type dopant such as Boron, for example, may be implanted into the upper surface of the N-type layer 620. In some implementations a dopant source such as Boron disc solid dopant source or a BBr3 liquid dopant source may be employed.

As shown in FIG. 6, two junctions are created, one at the interface between P-type layer 630 and N-type epitaxial layer 620 and the other between P-type substrate 610 and N-type epitaxial layer 620. As further shown in FIG. 6, the device may be provided with a mesa structure by etching mesa grooves. The grooves extend through the P-type layer 630, N-type layer 620 and at least a portion of the P-type layer 610. The mesa that is defined between the grooves forms the active area of the device. A passivation layer 640 is formed on the walls of the grooves. Any suitable passivation material may be employed, such as a thermally grown oxide, for example. Alternatively, in some cases a CVD nitride or glass passivation may be employed.

Metallization layers 650 and 660 are formed on the top and bottom surfaces of the device 600, respectively, to respectively establish an ohmic contact with the P-type layer 630 and the P-type substrate 610. In some implementations the metallization layers 650 and 660 may be formed, for example, from materials commonly used to form solder joints such as Ag or Ni—Au or materials commonly used to in wire bonding such as Al or Au.

An N-P-N bi-directional transient-voltage suppressor is also contemplated in accordance with subject matter disclosed herein. FIG. 7 shows schematic, cross-sectional view of one example of such an N-P-N bi-directional TVS 700.

The TVS 700 is formed on an N-type semiconductor substrate 710. On the N-type substrate 710 two regions or layers are grown. A first epitaxial P-type layer 720 is initially formed on the upper surface of N-type substrate 710. An N-type layer 730 is then formed on the upper surface of the P-type layer 720. The N-type layer 730 may be formed by an epitaxial deposition process. Alternatively, the N-type layer 730 may be formed using a doping process. For example, a N-type dopant such as phosphorus, for example, may be implanted into the upper surface of the P-type layer 720. In some implementations a dopant source such as arsenic implantation, phosphorus disc solid dopant source or a POCl₃ liquid dopant source may be employed.

As shown in FIG. 7, two junctions are created, one at the interface between N-type layer 730 and P-type epitaxial layer 720 and the other between N-type substrate 710 and P-type epitaxial layer 720. As further shown in FIG. 7, the device may be provided with a mesa structure by etching mesa grooves. The grooves extend through the N-type layer 730, P-type layer 720 and at least a portion of the N-type layer 710. The mesa that is defined between the grooves forms the active area of the device. A passivation layer 740 is formed on the walls of the grooves. Any suitable passivation material may be employed, such as a thermally grown oxide, for example. Alternatively, in some cases a CVD nitride or glass passivation may be employed.

Metallization layers 750 and 760 are formed on the top and bottom surfaces of the device 700, respectively, to respectively establish an ohmic contact with the N-type layer 730 and the N-type substrate 710. In some implementations the metallization layers 750 and 760 may be formed, for example, from materials commonly used to form solder joints such as Ag or Ni—Au or materials commonly used to in wire bonding such as Al or Au.

The TVS devices described above provide a number of advantages over conventional TVS devices. For example, during dice assembly the dice can be treated in the same way that uni-directional TVS or Zener dice are handled. Moreover, since layers are only formed on a single side of the dice with only metallization being applied to the other side, wafer processing is significantly simplified. Moreover, the thickness of the device can be substantially reduced because wafer thinning can be applied to the bottom side wafer during manufacturing without causing damage to the junctions or passivation layer. Wafer thinning may be performed, for example, by grinding the backside of the wafer after the semiconductor layers are formed but before metallization. The wafer may be thinned to some predefined target thickness (e.g., 8 mil, 6 mil, etc.). Accordingly, the devices may be configured as surface mount devices which are much thinner in height that conventional TVS surface mount devices.

The bi-directional TVS devices described herein are applicable to device having a wide range of different operating parameters. For example, devices may be provided which are operational at commonly employed breakdown voltages that range between 5V and 250V. The device may operate in accordance with punch-through breakdown or avalanche breakdown. The type of breakdown that arises may be determined, for example, by the thickness of the central N-type or P-type epitaxial layers (e.g., N-type layer 620 in FIG. 6 and P-type layer 720 in FIG. 7)

When the central N-type or P-type epitaxial layer is relatively thin, the top P/N junction (defined by layers 620 and 630 in FIG. 6 and layers 720 and 730 in FIG. 7) has a depletion width that may reach the bottom P/N junction (defined by substrate 610 and layer 620 in FIG. 6 and substrate 710 and layer 720 in FIG. 7). When the central N-type or P-type epitaxial layer is relatively thick, the top P/N junction has a depletion width that is much smaller than the thickness of the central N-type or P-type epitaxial layer.

In some particular embodiments the central N-type or P-type epitaxial layers may have a thickness in the range of about 10-50 microns. If the central epitaxial layer is too thin, the top and bottom junction diffusion profiles may merge with one another. On the other hand, if the central epitaxial layer is too thick, it could be difficult to use only a single passivation layer to protect both junctions. A suitable range of resistivities for the central epitaxial layer may be, by way of example, 0.001 ohm-cm to about 5 ohm-cm.

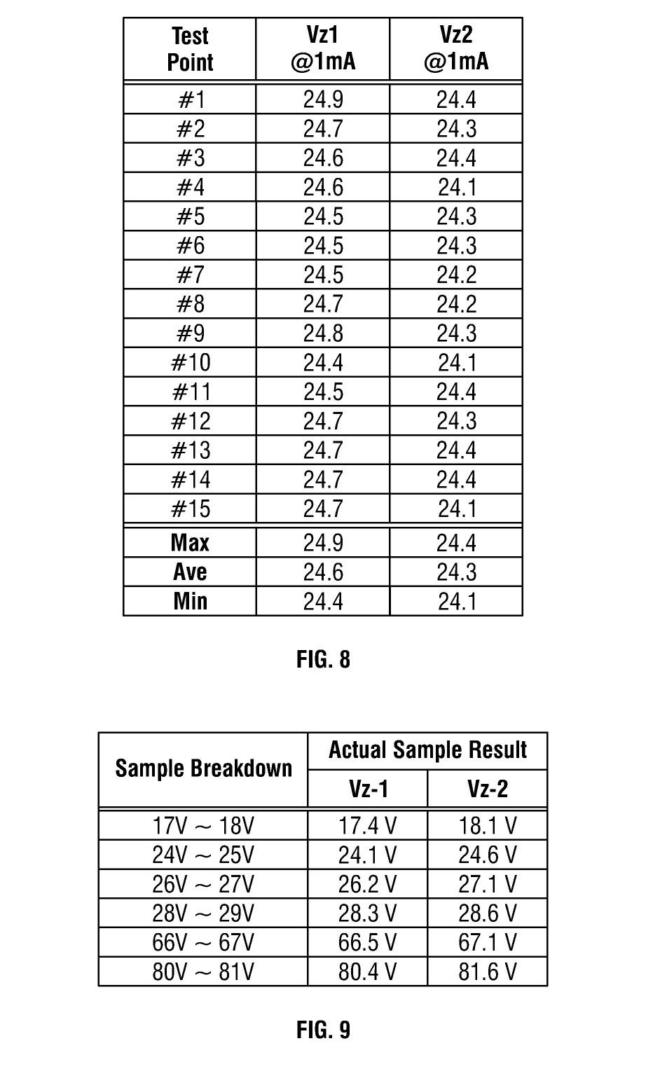

A series of bi-directional TVS devices were manufactured to demonstrate that a symmetric I-V curve can be achieved. FIG. 8 is a Table showing sample results for values of the breakdown voltages V_{z}1 and V_{z}2, which were each observed for opposite directions of the current. As is evident from the Table, the samples exhibit highly symmetric behavior. FIG. 9 is a Table showing results for samples that were manufactured to exhibit various breakdown voltages as indicated. The actual measured breakdown voltages V_{z}1 and V_{z}2 of the samples are also shown in the Table. Of course, the TVS devices described herein are not limited to the range of breakdown voltages illustrated in Table 9.

While exemplary embodiments and particular applications of this invention have been shown and described, it is apparent that many other modifications and applications of this invention are possible without departing from the inventive concepts herein disclosed. It is, therefore, to be understood that, within the scope of the appended claims, this invention may be practiced otherwise than as specifically described, and the invention is not to be restricted except in the spirit of the appended claims. Though some of the features of the invention may be claimed in dependency, each feature may have merit if used independently.

1. A bidirectional transient voltage suppressor, comprising:
a semiconductor substrate having a first conductivity type;
a first epitaxial semiconductor layer having a second conductivity type formed on a first side of the semiconductor substrate;
a second semiconductor layer having the first conductivity type formed on the first epitaxial semiconductor layer; and
first and second metallization layers disposed on a second side of the semiconductor substrate and the second semiconductor layer, respectively.

2. The bidirectional transient voltage suppressor of claim 1, further comprising grooves extending into at least the first and second semiconductor layers to form a mesa structure therebetween, the mesa structure defining an active area of the transient voltage suppressor.

3. The bidirectional transient voltage suppressor of claim 2, wherein the grooves further extend into the semiconductor substrate.

4. The bidirectional transient voltage suppressor of claim 2, further comprising a passivation layer disposed over sidewalls of the mesa structure.

5. The bidirectional transient voltage suppressor of claim 4, wherein the passivation layer protects both first and second junctions, the first junction being located between the substrate and the first layer and the second junction being located between the first layer and the second layer.

6. The bidirectional transient voltage suppressor of claim 1, wherein the second semiconductor layer is an epitaxial layer.

7. The bidirectional transient voltage suppressor of claim 1, wherein the second semiconductor layer is an implantation layer having a dopant of the first conductivity type implanted in the first epitaxial semiconductor layer.

8. The bidirectional transient voltage suppressor of claim 1, wherein the first epitaxial layer has a resistivity between 0.001 ohm-cm and 5 ohm-cm.

9. The bidirectional transient voltage suppressor of claim 1, wherein the first epitaxial layer has a thickness between 10 microns and 50 microns.

10. The bidirectional transient voltage suppressor of claim 1, wherein the transient voltage suppressor has a breakdown voltage between 5V and 250V.

11. A method of forming a bidirectional transient voltage suppressor, comprising:
forming a first epitaxial semiconductor layer having a second conductivity type formed on a first side of semiconductor substrate having a first conductivity type;
forming a second semiconductor layer having the first conductivity type on the first epitaxial semiconductor layer; and
forming first and second metallization layers on a second side of the semiconductor substrate and the second semiconductor layer, respectively.

12. The method of claim 11, further comprising forming grooves that extend into at least the first and second semiconductor layers to form a mesa structure therebetween, the mesa structure defining an active area of the transient voltage suppressor.

13. The method of claim 12, wherein the grooves further extend into the semiconductor substrate.

14. The method of claim 12, further comprising forming a passivation layer disposed over sidewalls of the mesa structure.

15. The method of claim 11, further comprising forming the second semiconductor layer using a deposition process.

16. The method of claim 15, wherein the deposition process is an epitaxial deposition process.

17. The method of claim 11, further comprising thinning the substrate on its second side.

18. The method of claim 11, further comprising forming the second semiconductor layer using an implantation process with a dopant of the first conductivity type implanted in the first epitaxial semiconductor layer.
